(19) United States
(12) Patent Application Publication
(10) Pub. No.: US 2025/0263841 A1
(43) Pub. Date: Aug. 21, 2025

(54) SUBSTRATE PROCESSING APPARATUS AND POSITION DETECTION METHOD

(71) Applicant: Tokyo Electron Limited, Tokyo (JP)

(72) Inventors: Hikaru SATO, Iwate (JP); Yuta HAGA, Iwate (JP)

(21) Appl. No.: 19/046,973

(22) Filed: Feb. 6, 2025

(30) Foreign Application Priority Data
Feb. 21, 2024 (JP) 2024-024619

(51) Int. Cl. C23C 16/52; C23C 16/455; C23C 16/458; G06T 7/50; G06T 7/73

(52) U.S. Cl. CPC C23C 16/52; C23C 16/45544; C23C 16/4584; G06T 7/50; G06T 7/73; G06T 2207/20061

(57) ABSTRACT

A substrate processing apparatus includes a processing container, a rotary table rotatably provided inside the processing container and including a stage on which a substrate is placed, an imaging device fixed to the processing container and that captures an image of a portion of the rotary table, and a control unit that processes imaging information of the imaging device. The rotary table includes at least two rotation-side imaging targets spaced apart from each other at positions corresponding to the stage. The control unit rotates the rotary table such that, when an image of the rotary table is captured, the imaging device is located between the two rotation-side imaging targets in a plan view of the imaging device and the rotary table. An intermediate correction lens is provided between the imaging device and the rotary table to correct a viewing angle direction of the imaging device.

### CROSS-REFERENCE TO RELATED APPLICATIONS

This application is based on and claims priority from Japanese Patent Application No. 2024-024619, filed on Feb. 21, 2024, with the Japan Patent Office, the disclosure of which is incorporated herein in its entirety by reference.

### TECHNICAL FIELD

The present disclosure relates to a substrate processing apparatus and a position detection method.

### BACKGROUND

Japanese Patent Laid-Open Publication No. 2012-094814 discloses a substrate processing apparatus in which substrates are respectively placed on a plurality of stages of a rotary table serving as a susceptor to perform a substrate processing such as a film forming process. This substrate processing apparatus has a camera installed in a processing container. Images of two susceptor marks on the rotary table are captured by the camera, and the position of the stage is corrected based on the imaging information. The substrate is then transported to the stage of which the position has been corrected.

### SUMMARY

According to an aspect of the present disclosure, a substrate processing apparatus includes: a processing container; a rotary table rotatably provided inside the processing container and having a stage on which a substrate is placed; an imaging device fixed to the processing container and capable of capturing an image of a portion of the rotary table; and a control unit that processes imaging information of the imaging device. The rotary table includes at least two rotation-side imaging targets spaced apart from each other at positions corresponding to the stage. The control unit rotates the rotary table such that, when an image of the rotary table is captured, the imaging device is located between the two rotation-side imaging targets in a plan view of the imaging device and the rotary table. An intermediate correction lens is provided between the imaging device and the rotary table in a side view of the imaging device and the rotary table, to correct a viewing angle direction of the imaging device in a direction orthogonal to a surface of the rotary table.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating a substrate processing apparatus according to an embodiment.

FIG. 2 is a schematic plan view illustrating the interior of a processing container of the substrate processing apparatus.

FIG. 3 is a side cross-sectional view along line III-III in FIG. 2.

FIG. 4A is a schematic diagram illustrating the viewing angle direction of an imaging device to which an intermediate correction lens is applied. FIG. 4B is a schematic diagram illustrating the viewing angle direction of the imaging device in a case where an intermediate correction lens according to a reference example is not provided.

FIG. 5 is a diagram illustrating a method of recognizing the position of a stage.

FIG. 6 is a flowchart illustrating a process flow of a position detection method.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment of the present disclosure will be described with reference to the accompanying drawings. In the drawings, the same components are denoted by the same reference numerals, and duplicated descriptions may be omitted.

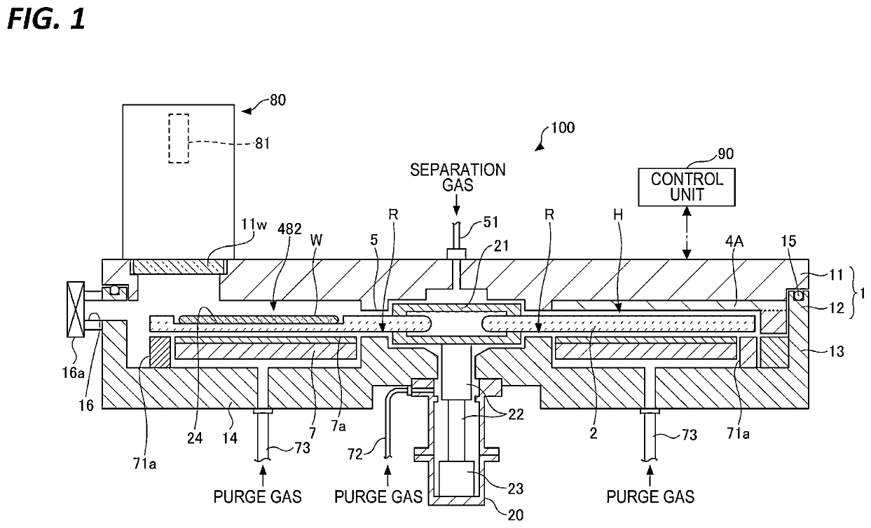

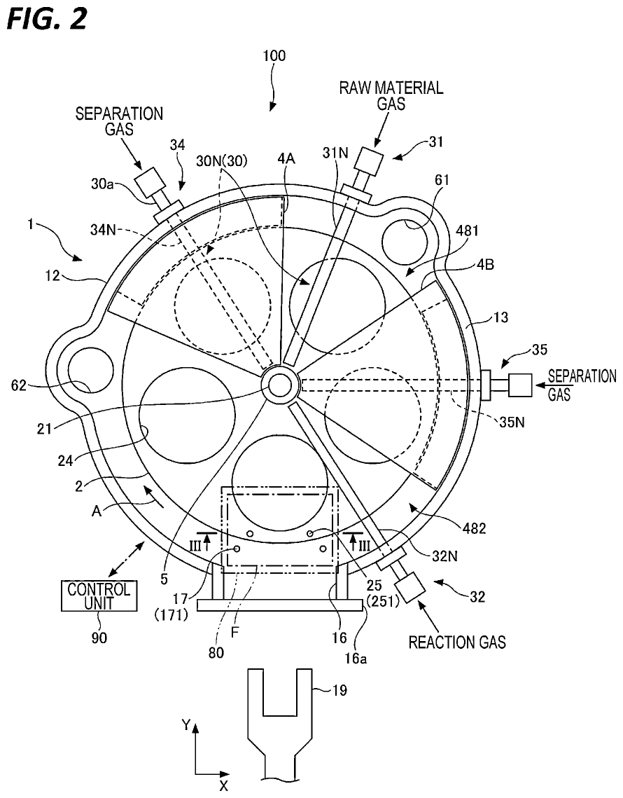

FIG. 1 is a schematic cross-sectional view illustrating a substrate processing apparatus 100 according to an embodiment. FIG. 2 is a schematic plan view illustrating the interior of a processing container 1 of the substrate processing apparatus 100. As illustrated in FIGS. 1 and 2, the substrate processing apparatus 100 is configured as a film forming apparatus that forms a film on the surface of a substrate W using atomic layer deposition (ALD) or molecular layer deposition (MLD). A substrate processing performed by the substrate processing apparatus 100 is not limited to the film forming processing, and may be, for example, an etching processing or a cleaning processing.

The substrate processing apparatus 100 includes a processing container 1 for housing the substrate W therein and performing a film forming processing, and a rotary table 2 which is rotatably provided within the processing container 1.

The processing container 1 is formed in a flat cylindrical shape and has a processing chamber therein for housing the substrate W. For example, the processing container 1 is configured by assembling a container body 12 having an open upper surface and a top plate 11 disposed on the upper portion of the container body 12. For the convenience of description, the top plate 11 is not illustrated in FIG. 2. The container body 12 includes a disc-shaped bottom 14 and a side 13 that protrudes vertically upward from the outer edge of the bottom 14. The side 13 of the container body 12 and the top plate 11 are air-tightly fixed to each other with a seal member 15 such as, for example, an O-ring interposed therebetween. In addition, a position detection device 80 is installed on the top plate 11. The configuration of this position detection device 80 will be described later in detail.

The rotary table 2 is formed in an annular shape, and has an inner periphery fixed to a cylindrical core 21. The core 21 is fixed to the upper end of a rotating shaft 22 extending in the vertical direction. The rotating shaft 22 passes through the bottom 14 of the processing container 1, and has a lower end held by a driving unit 23. The driving unit 23 rotates the rotating shaft 22 about an axis. Thus, the rotary table 2 rotates around the center of the processing container 1 through the rotating shaft 22 and the core 21.

The rotating shaft 22 and the driving unit 23 are housed in a cylindrical case body 20 having an open upper surface. The case body 20 has a flange at the upper end, and is air-tightly fixed to the bottom 14 of the processing container 1. The internal space of the case body 20 is thus isolated from the outside of the case body 20 and is communication with the processing chamber of the processing container 1.

As illustrated in FIGS. 1 and 2, the rotary table 2 has, on the upper surface, a plurality of (e.g., five in FIG. 2) circular and concave stages 24 (recesses) on which the substrate W may be placed, provided in the direction of rotation of the rotary table 2. Examples of the substrate W on which a film forming processing is performed include semiconductor wafers such as silicon semiconductors, compound semiconductors, or oxide semiconductors. The substrate W may have recesses and protrusions such as trenches and vias on the surface.

The stage 24 has an inner diameter slightly larger than the diameter (e.g., 300 mm) of the substrate W and a depth approximately equal to the thickness of the substrate W. As a result, in a state where the substrate W is placed on the stage 24, the upper surface of the rotary table 2 (a region where the substrate W is not placed) and the upper surface of the substrate W are approximately at the same height.

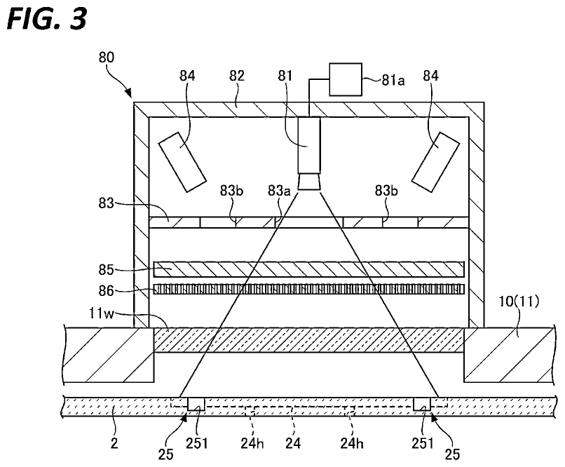

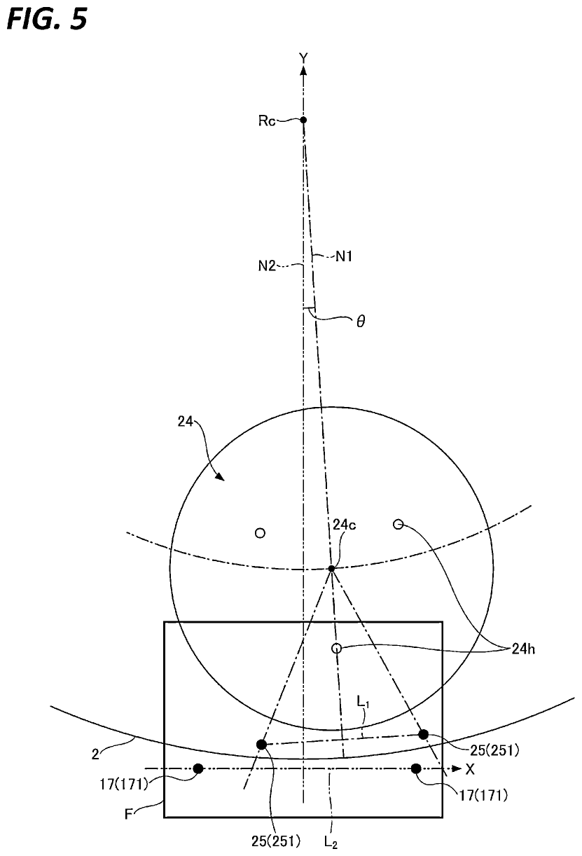

In addition, each stage 24 of the rotary table 2 has a plurality of (e.g., three) through holes 24h (see, e.g., FIGS. 3 and 5). The processing container 1 includes a lifter (not illustrated) at a position adjacent to a transport port 16 provided on the side 13. The lifter has a plurality of (e.g., three) lift pins that move up and down through each through hole 24h to receive and deliver the substrate W to and from a transport device that enters through the transport port 16.

The substrate processing apparatus 100 includes a gas supply unit 30 for supplying a gas into the inside of the processing container 1. The gas supply unit 30 is formed of, for example, quartz and includes a plurality of gas nozzles 30N that extend linearly. Each gas nozzle 30N has an introduction port 30a, which is a base end, fixed to the side 13 of the processing container 1, and extends radially inside the processing container 1 to near the central region. Each gas nozzle 30N extends parallel to the upper surface of the rotary table 2 in the processing container 1. Each gas nozzle 30N has a plurality of gas discharge holes (not illustrated) opening toward the rotary table 2 in a thick wall on the vertically downward side. The gas discharge holes are arranged, for example, at equal intervals in the axial direction (the radial direction of the processing container 1).

The gas supply unit 30 includes a raw material gas supply unit 31 that supplies a raw material gas, a reaction gas supply unit 32 that supplies a reaction gas, and a first separation gas supply unit 34 and a second separation gas supply unit 35 that supply a separation gas. Each of the raw material gas supply unit 31, the reaction gas supply unit 32, the first separation gas supply unit 34, and the second separation gas supply unit 35 is provided with one or more gas nozzles 30N. In the example of FIG. 2, a second separation gas nozzle 35N, a raw material gas nozzle 31N, a first separation gas nozzle 34N, and a reaction gas nozzle 32N are installed in this order clockwise from the transport port 16.

The raw material gas nozzle 31N is connected to a raw material gas supply path (not illustrated). The raw material gas supply path is provided with a raw material gas source, an opening/closing valve, a flow rate controller, and the like (none of which are illustrated) to supply a raw material gas to the raw material gas nozzle 31N. As the raw material gas, any appropriate gas may be used depending on the type of the film to be formed on the substrate W, and the like.

The reaction gas nozzle 32N is connected to a reaction gas supply path (not illustrated). The reaction gas supply path is provided with, for example, a reaction gas source, an opening/closing valve, and a flow rate controller (none of which are illustrated) to supply a reaction gas to the reaction gas nozzle 32N. As the reaction gas, any appropriate gas may be used depending on, for example, the type of the film to be formed on the substrate W.

The first separation gas nozzle 34N and the second separation gas nozzle 35N are each connected to a gas supply source of separation gas (not illustrated). Examples of the separation gas include an inert gas such as nitrogen (N₂) gas or a noble gas.

In addition, the processing container 1 has two protrusions 4A and 4B attached to the lower surface of the top plate 11 (see also FIG. 1). The protrusions 4A and 4B are generally fan-shaped in a plan view, spaced apart from each other in the circumferential direction of the processing container 1 and located above the rotary table 2. The central sides of the protrusions 4A and 4B are in close proximity to a protruding portion 5 attached to the top plate 11. The protrusions 4A and 4B are formed of a metal such as, for example, aluminum. The protrusion 4A has a groove (not illustrated) extending radially in the circumferential middle portion, and houses the first separation gas nozzle 34N in this groove. The protrusion 4B also has a groove (not illustrated) extending radially in the circumferential middle portion, and houses the second separation gas nozzle 35N in this groove. Meanwhile, the processing container 1 has a first region 481 in which the raw material gas nozzle 31N is disposed and a second region 482 in which the reaction gas nozzle 32N is disposed between the protrusion 4A and the protrusion 4B located in the circumferential direction.

The protrusions 4A and 4B forms a separation space H (see, e.g., FIG. 1) between these protrusions and the rotary table 2. When a separation gas is supplied from the first separation gas nozzle 34N and the second separation gas nozzle 35N, the separation gas flows from the separation space H toward the first region 481 and the second region 482. Since the height of the separation space H is lower than that of the first region 481 and the second region 482, the pressure in the separation space H may be maintained higher than the pressure in the first region 481 and the second region 482. This allows the separation space H to form a pressure barrier against the first region 481 and the second region 482 to reliably separate the first region 481 and the second region 482 from each other.

Referring back to FIG. 1, a separation gas supply pipe 51 is connected to the center of the top plate 11. By supplying the separation gas, the separation gas supply pipe 51 makes it possible for the pressure in the space between the core 21 and the top plate 11, the space between the outer periphery of the core 21 and the inner periphery of the protruding portion 5, and the space between the protruding portion 5 and the rotary table 2 to be maintained higher than the pressure in the first region 481 and the second region 482.

In addition, an annular heater unit 7 serving as a heater is provided in the space between the rotary table 2 and the bottom of the container body 12. The heater unit 7 heats each substrate W placed on the stage 24 with the rotary table 2 interposed therebetween to a target temperature. In addition, a block member 71a is provided below the rotary table 2 and near the outer periphery thereof so as to surround the heater unit 7. Therefore, the space in which the heater unit 7 is placed is partitioned from the region outside the heater unit 7. The block member 71a is disposed so that a small gap is maintained between the block member and the lower surface of the rotary table 2. In order to purge a region in which the heater unit 7 is housed, a plurality of purge gas supply pipes 73 for supplying a purge gas are connected to this region so as to pass through the bottom of the container body 12. A protective plate 7a is disposed above the heater unit 7. The protective plate 7a is formed of quartz or the like, and protects the heater unit 7 even when processing gas flows into the space in which the heater unit 7 is provided.

In addition, the bottom of the container body 12 has a ridge R on the inside of the annular heater unit 7. The upper surface of the ridge R is positioned close to the rotary table 2 and the core 21, with a small gap left between the upper surface of the ridge R and the rear surface of the rotary table 2 and between the upper surface of the ridge R and the rear surface of the core 21. The bottom 14 of the container body 12 has a central hole through which the rotating shaft 22 passes. The inner diameter of this central hole is slightly larger than the diameter of the rotating shaft 22, with a gap that communicates with the case body 20 left therein. A purge gas supply pipe 72 is connected to the upper portion of the case body 20.

The purge gas supply pipe 72 supplies a purge gas into the case body 20. This purge gas flows into the space below the heater unit 7 through the gap between the rotating shaft 22 and the central hole of the bottom 14, the gap between the core 21 and the ridge R of the bottom 14, and the gap between the ridge R and the rear surface of the rotary table 2. Further, the purge gas flows through the gap between the block member 71a and the rear surface of the rotary table 2 into exhaust ports 61 and 62 to be described later. Examples of the purge gas supplied by the purge gas supply pipe 72 and purge gas supply pipe 73 include an inert gas such as nitrogen gas or a noble gas, similarly to the separation gas.

As illustrated in FIG. 2, the processing container 1 includes an exhaust port 61 in the first region 481 and includes an exhaust port 62 in the second region 482. The exhaust ports 61 and 62 are connected to an exhaust system including, for example, a pressure regulator, a turbo molecular pump, and the like. The substrate processing apparatus 100 may adjust the pressure in the processing container 1 through the exhaust system. The exhaust ports 61 and 62 may promote a reduction in the pressure in the first region 481 and the pressure in the second region 482 by exhausting the gas in the first region 481 and the gas in the second region 482. The raw material gas supplied from the raw material gas nozzle 31N is generally exhausted from the exhaust port 61, and the reaction gas supplied from the reaction gas nozzle 32N is generally exhausted from the exhaust port 62.

In addition, the substrate processing apparatus 100 includes a control unit 90 that controls the operation of the entire apparatus. The control unit 90 is a computer having a processor, a memory, an input and output interface, and a communication interface (not illustrated). The processor is an electronic circuit including one or a combination of components such as a central processing unit (CPU), a graphics processing unit (GPU), an application specific integrated circuit (ASIC), a field-programmable gate array (FPGA), or a circuit made up of a plurality of discrete semiconductors, and executes and processes programs stored in the memory. The memory includes a main storage device such as a semiconductor memory, and an auxiliary storage device such as a disk or a semiconductor memory (flash memory).

FIG. 3 is a cross-sectional view along line III-III in FIG. 2. As illustrated in FIG. 3, the substrate processing apparatus 100 includes the position detection device 80 for detecting the position of each stage 24 when the substrate W is placed on each stage 24 of the rotary table 2. The position detection device 80 is fixed to the upper portion of the top plate 11 of the processing container 1 (the outside of the processing container 1).

The position detection device 80 includes an imaging device 81 that captures an image of the rotary table 2, a housing 82 that houses the imaging device 81, a panel 83 provided below the imaging device 81, a light source 84 that irradiates an imaging target with light, an intermediate correction lens 85 that changes the viewing angle direction of the imaging device 81, and a polarizing plate 86 that regulates reflected light. In addition, the top plate 11 of the processing container 1 has a transmission window 11w installed thereon so that the image of the rotary table 2 may be captured by the imaging device 81. The transmission window 11w and the position detection device 80 are disposed adjacent to the transport port 16 (see also FIG. 2). This allows the position detection device 80 to properly detect the position of the stage 24 of the rotary table 2 that has moved to the vicinity of the transport port 16.

The imaging device 81 is provided at a position spaced apart from the transmission window 11w by an imaging distance set in the vertical direction. The type of imaging device 81 is not particularly limited, and, for example, a camera having a charge coupled device (CCD) sensor or a complementary metal oxide semiconductor (CMOS) sensor may be applied. The imaging device 81 is attached to the upper portion inside the housing 82, with an internal lens facing the vertically downward side. This allows the imaging device 81 to capture images of a portion of the rotary table 2 and a periphery thereof through the transmission window 11w of the top plate 11. The imaging device 81 causes an imaging control unit 81a connected thereto to control on/off switching, focusing, imaging, or the like, and to process imaging information on captured images. The imaging control unit 81a may also serve as the control unit 90.

The housing 82 is formed in a cylindrical shape, holds the imaging device 81 at the upper portion, and blocks light from the surroundings in the imaging direction of the imaging device 81. The lower end of the housing 82 is formed as an opening, and the housing 82 is installed on the top plate 11 with the opening facing the transmission window 11w. In addition, the housing 82 may be provided with a cooling mechanism (not illustrated) that cools the imaging device 81. The cooling mechanism may have, for example, a configuration in which a fan (not illustrated) blows air onto the imaging device 81 and the light source 84, and exhausts the air from an opening (not illustrated).

The panel 83 is provided between the imaging device 81 and the transmission window 11w which are aligned vertically in a side view. The panel 83 has an aperture 83a in a central portion thereof. The imaging device 81 captures an image of an imaging range F defined by the aperture 83a. Specifically, as illustrate in FIG. 2, the imaging range F is defined so a portion of the outer periphery of the rotary table 2 and a portion of the container body 12 are captured in the image. In addition, the imaging range F is defined such that the radially outer side of the stage 24 that has moved due to the rotation of the rotary table 2 is captured in the image.

Here, the rotary table 2 is provided in advance with two rotation-side imaging targets 25 corresponding to each of a plurality of stages 24. The position detection device 80 sets the imaging distance of the imaging device 81 and the position or size of the aperture 83a such that the two rotation-side imaging targets 25 are entered therein. In addition, the processing container 1 also has two fixed-side imaging targets 17 so as to be adjacent to the two rotation-side imaging targets 25 that have moved due to the rotation of the rotary table 2. In other words, the position detection device 80 may capture images of the two rotation-side imaging targets 25 and the two fixed-side imaging targets 17 using the imaging device 81, and detects the position of the rotary table 2 in the rotational direction (circumferential direction) based on the imaging information.

Each rotation-side imaging target 25 and each fixed-side imaging target 17 are formed in a perfect circular shape in a plan view. However, the shapes of the rotation-side imaging target 25 and the fixed-side imaging target 17 are not particularly limited, and may be, for example, polygonal or elliptical. In addition, each fixed-side imaging target 17 is formed to have a size (diameter) slightly larger than each rotation-side imaging target 25. This allows the imaging control unit 81a to easily identify each rotation-side imaging target 25 and each fixed-side imaging target 17 of which the images have been captured.

Referring back to FIG. 3, each rotation-side imaging target 25 is formed in a recess 251 recessed from the surface (upper surface) of the rotary table 2 in a thickness direction. By carving the recess 251 into the rotary table 2 in this way, a luminance difference occurs between the surface of the rotary table 2 and the surface of the recess 251. The imaging control unit 81a extracts the edge of the rotation-side imaging target 25 from this luminance difference, and further recognizes the circle of the recess 251 by using a Hough transform algorithm. In addition, similarly, each fixed-side imaging target 17 is also formed in a recess 171 (see, e.g., FIG. 2) recessed from the surface (upper surface) of the bottom 14 of the container body 12 in the thickness direction. The rotation-side imaging target 25 and the fixed-side imaging target 17 are not limited to the configurations of only the recesses 251 and 171, and may be configured with, for example, a black marker or the like housed therein.

The light source 84 of the position detection device 80 is attached so as to irradiate the imaging range F defined by the aperture 83a with light through a hole 83b in the panel 83 and the transmission window 11w. The light source 84 may be, for example, an illumination device having a white light-emitting diode (LED), and the brightness is adjusted by a driving unit (not illustrated). In FIG. 3, the configuration has two light sources 84 to ensure brightness, but the number of light sources 84 is not particularly limited, and may be one, or three or more. In addition, the light source 84 may be installed at a changeable angle. The light source 84 irradiates the rotary table 2 with light, so that the two rotation-side imaging targets 25 and the two fixed-side imaging targets 17 are appropriately illuminated.

The intermediate correction lens 85 is provided between the imaging device 81 and the rotary table 2 in a side view of the imaging device 81 and the rotary table 2. The intermediate correction lens 85 may be formed of transparent quartz or a resin material. More specifically, the intermediate correction lens 85 is disposed below the panel 83 and at a position away from the transmission window 11w. The intermediate correction lens 85 has a function of correcting the viewing angle direction of the imaging device 81 in a direction orthogonal to the surface of the rotary table 2.

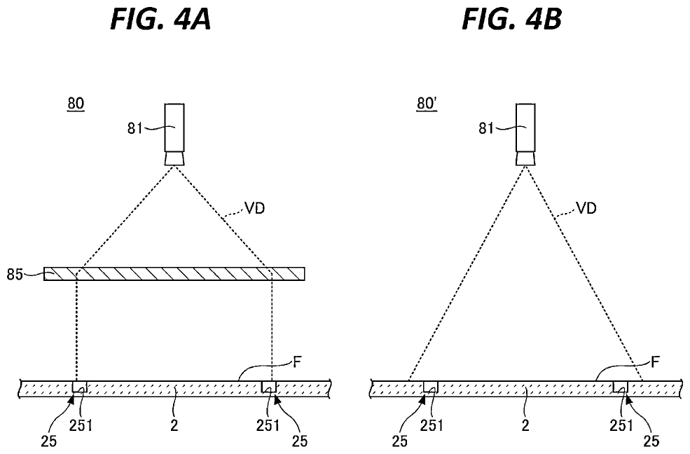

FIG. 4A is a schematic diagram illustrating the viewing angle direction VD of the imaging device 81 to which the intermediate correction lens 85 is applied. FIG. 4B is a schematic diagram illustrating the viewing angle direction VD of the imaging device 81 in a case where the intermediate correction lens 85 according to a reference example is not provided. The imaging device 81 is configured so that the angle of view is formed by an imaging lens housed inside, whereby the viewing angle direction VD becomes more diagonal to the side as it moves toward the outside of the imaging range F as illustrated in FIGS. 4A and 4B. In positioning the stage 24, the imaging device 81 basically captures images at the middle positions of the two fixed-side imaging targets 17 and the two rotation-side imaging targets 25 (see, e.g., FIG. 2). Therefore, the two fixed-side imaging targets 17 and the two rotation-side imaging targets 25 are each located closer to the edge of the imaging range F.

As illustrated in FIG. 4B, a position detection device 80′ according to the reference example captures an image of the imaging range F without correcting the viewing angle direction VD, so that each fixed-side imaging target 17 and each rotation-side imaging target 25 are viewed diagonally to the side, and it is not possible to capture an image as if viewed from directly above. In other words, the imaging device 81 captures imaging information for the recess 171 of each fixed-side imaging target 17 and the recess 251 of each rotation-side imaging target 25, in which the edge of the opening and the edge of the bottom are doubled. In this case, the acquisition of double circles in the image processing of the imaging control unit 81a makes it difficult for the control unit 90 to determine the accurate positions of each fixed-side imaging target 17 and each rotation-side imaging target 25.

For this reason, the position detection device 80 according to the embodiment performs image capture using the imaging device 81 through the intermediate correction lens 85, as illustrated in FIG. 4A. The intermediate correction lens 85 bends the viewing angle direction VD of the imaging device 81 to thereby correct the optical path to be perpendicular to the surface of the bottom 14 of the container body 12 and the surface of the rotary table 2 (in other words, each fixed-side imaging target 17 and each rotation-side imaging target 25). That is, the intermediate correction lens 85 reduces the effect of the angle of view caused by the lens in the imaging device 81 as described above, and sets the viewing angle direction VD as if each fixed-side imaging target 17 and each rotation-side imaging target 25 are viewed from directly above. This allows the imaging device 81 to obtain imaging information in which the recess 171 of each fixed-side imaging target 17 and the recess 251 of each rotation-side imaging target 25 do not appear double.

The intermediate correction lens 85 applied to the position detection device 80 has no particular limitation on structure insofar as it may correct the viewing angle direction VD in the vertical direction. For example, the intermediate correction lens 85 may be appropriately selected from a convex lens, a Fresnel lens, a cylindrical lens, and a combination of a convex lens and a concave lens. In addition, the intermediate correction lens 85 is formed in a rectangular of elliptical shape having a major axis in the extending direction of the transmission window 11w in a plan view. The size of the intermediate correction lens 85 may be, for example, approximately the same as that of the transmission window 11w. The intermediate correction lens 85 may also guide light which is approximately perpendicular to each fixed-side imaging target 17 and each rotation-side imaging target 25 by making the light from the light source 84 approximately parallel to the vertical direction.

The position detection device 80 refracts the optical paths of the imaging device 81 and the light source 84 to thereby change the reflection position of light that hits the rotary table 2 and the container body 12 and the intensity of reflected light. For this reason, there is concern of strong reflected light being generated at specific positions of the rotary table 2 and the container body 12. In order to suppress the imaging device 81 from capturing an image of this local reflected light, the position detection device 80 includes a polarizing plate 86 between the intermediate correction lens 85 and the rotary table 2.

The polarizing plate 86 removes the local reflected light from the rotary table 2 and the container body 12 by adjusting the reflected light that vibrates in all directions to light that vibrates only a specific direction. A well-known configuration may be applied to the polarizing plate 86. Alternatively, the polarizing plate 86 may be configured to be disposed on the light source 84 side to polarize the irradiation light from the light source 84 in advance.

In addition, in a case where the intermediate correction lens 85 and the polarizing plate 86 are applied, the imaging device 81 may acquire imaging information which is dark overall (low in luminance). For this reason, the imaging device 81 is recommended to perform a processing of adjusting the imaging information to achieve appropriate luminance in the image processing performed by the imaging control unit 81a. An example of the image processing performed by the imaging control unit 81a is a high dynamic range (HDR) processing.

The imaging control unit 81a extracts information on each fixed-side imaging target 17 and each rotation-side imaging target 25 from the imaging information by performing a further image processing on the imaging information that has undergone the HDR processing. An example of the processing of extracting each fixed-side imaging target 17 and each rotation-side imaging target 25 is Hough transform. By performing the Hough transform, it is possible to detect the circle of each fixed-side imaging target 17 and the circle of each rotation-side imaging target 25. As described above, the imaging information of the imaging device 81 is corrected by the intermediate correction lens 85, which prevents the openings and bottoms of the recesses 171 and 251 from being doubled. Therefore, the imaging control unit 81a may easily obtain the circle of each fixed-side imaging target 17 and the circle of each rotation-side imaging target 25 with few errors (candidates) in the Hough transform.

The control unit 90 recognizes the position of each stage 24 of the rotary table 2 facing the position detection device 80 by using information on the circle of the fixed-side imaging target 17 and the circle of each rotation-side imaging target 25 obtained from the imaging device 81.

FIG. 5 is a diagram illustrating a method of recognizing the position of the stage 24. Specifically, the control unit 90 detects the position of each target from the circle of the fixed-side imaging target 17 and the circle of each rotation-side imaging target 25 acquired from the imaging device 81.

Here, the two rotation-side imaging targets 25 are disposed symmetrically with respect to a straight line passing through a center 24c of the stage 24 and a rotation center Rc of the rotary table 2. In other words, when a perpendicular line N1 is drawn from the rotation center 2c of the rotary table 2 to a segment L1 connecting the centers of the two rotation-side imaging targets 25, this perpendicular line N1 passes through the center 24c of the stage 24 and intersects the midpoint of the segment L1. That is, the perpendicular line N1 is the perpendicular bisector of the segment L1.

In addition, when a perpendicular line N2 is drawn from the rotation center Rc of the rotary table 2 to a segment L2 connecting the centers of the two fixed-side imaging targets 17, this perpendicular line N2 intersects the midpoint of the segment L2. That is, the perpendicular line N2 is the perpendicular bisector of the segment L2.

The angle θ between the perpendicular line N1 and the perpendicular line N2 is the shift of the stage 24 when the rotary table 2 is rotated to place the substrate W. That is, in a case where the angle θ is approximately zero, the stage 24 may be assumed to be disposed at a normal position where the substrate W may be placed, whereas in a case where the angle θ is greater than a predetermined value, the shift of the stage 24 may be assumed to need to be adjusted.

In a case where the shift of the stage 24 is adjusted, the control unit 90 is recommended to perform a processing of rotating the rotary table 2 by the shift amount based on the detected angle θ and the position of the center 24c of the stage 24. This ensures that the angle θ becomes zero and the stage 24 is appropriately positioned, which makes it possible for the substrate W to be accurately placed on the stage 24 by the transport device.

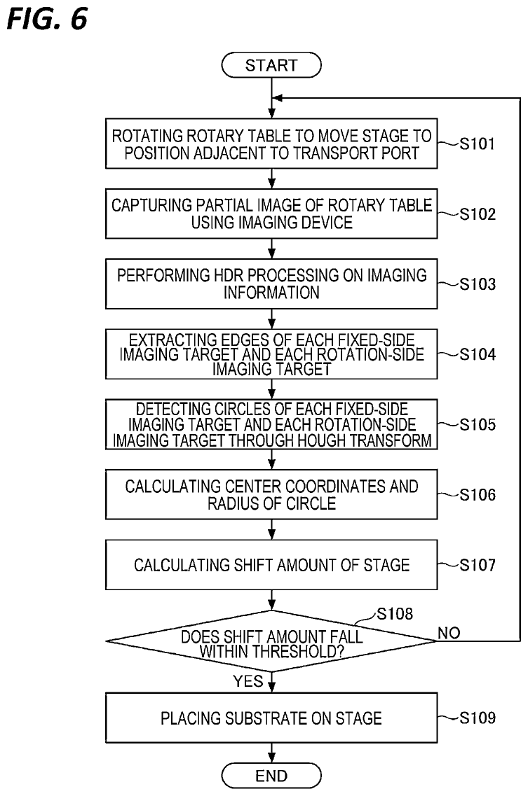

The substrate processing apparatus 100 according to the embodiment is basically configured as described above, and a method of detecting the position of the stage 24 when the substrate W is placed will be described below with reference to FIG. 6. FIG. 6 is a flowchart illustrating a process flow of the position detection method.

The control unit 90 and the imaging control unit 81a of the substrate processing apparatus 100 control steps S101 to S109 in the position detection method.

Specifically, in the position detection method, the substrate processing apparatus 100 rotates the rotary table 2 to move the stage 24 which is a target to a position adjacent to the transport port 16 of the processing container 1 (step S101). This movement causes the imaging device 81 to be located between the two rotation-side imaging targets 25 in a plan view of the imaging device 81 and the rotary table 2.

Next, the control unit 90 operates the imaging device 81 of the position detection device 80 and captures an image of a portion of the rotary table 2 including the stage 24 using the imaging device 81 to start detecting the position of the stage 24 (step S102). As described above, the imaging control unit 81a captures images of the two fixed-side imaging targets 17 and the two rotation-side imaging targets 25 through the intermediate correction lens 85 to thereby acquire imaging information having these imaging targets.

When the imaging information is acquired, the imaging control unit 81a performs the HDR processing on the imaging information whose luminance has been decreased by passing through the intermediate correction lens 85 and the polarizing plate 86, to thereby improve the luminance (step S103).

Next, the imaging control unit 81a generates an edge detection image by extracting the edges of each fixed-side imaging target 17 and each rotation-side imaging target 25 based on the luminance change in the imaging information with improved luminance (step S104). For example, the edge detection image is information on a binary image in which areas where the luminance change is equal to or greater than a threshold are set to be white, and areas where the luminance change is less than the threshold are set to be black.

The imaging control unit 81a performs a processing of detecting the circle of each fixed-side imaging target 17 and the circle of each rotation-side imaging target 25 from the edge detection image through the Hough transform (step S105). This allows the imaging control unit 81a to obtain the circles of the two fixed-side imaging targets 17 and the circles of the two rotation-side imaging targets 25 (four circles in total) described above. The imaging control unit 81a transmits the extracted images for the circles of the two fixed-side imaging targets 17 and the circles of the two rotation-side imaging targets 25 to the control unit 90.

When the extracted images are acquired, the control unit 90 calculates the center coordinates (that is, the positions of each fixed-side imaging target 17 and each rotation-side imaging target 25) and the radius of each circle from the extracted images (step S106).

Further, the control unit 90 calculates the angle θ between the perpendicular line N1 and the perpendicular line N2 described above and the position of the center 24c of the stage 24 based on the calculated positions of each fixed-side imaging target 17 and each rotation-side imaging target 25 (step S107). This angle θ represents the shift amount of the stage 24 as described above.

The control unit 90 determines whether the shift amount (angle θ) of the stage 24 falls within a threshold (step S108). In a case where the shift amount exceeds the threshold (step S108: NO), the process returns to step S101, and the rotary table 2 is rotated to readjust the position of the stage 24. In this case, the rotary table 2 need only be rotated based on the angle θ detected in step S107. Meanwhile, in a case where the shift amount falls within the threshold (step S108: YES), the process proceeds to step S109.

In step S109, the control unit 90 controls the transport device to load the substrate W into the processing container 1 using the transport device and place the substrate W on the stage 24. In this case, the control unit 90 may finely adjust the position of the substrate W using the transport device based on the position of the center 24c of the stage 24 calculated in step S107. In addition, the substrate processing apparatus 100 is configured with the shift amount of the rotational position of the rotary table 2 falling within the threshold. Therefore, when each lift pin is raised from each through hole 24h, contact of each lift pin with the rotary table 2 may be avoided. This allows the substrate processing apparatus 100 to stably place the substrate W on the stage 24.

In the above-described position detection method, the processing of loading the substrate W onto the stage 24 has been described as an example, but there is no limitation thereto. The same applies to a processing of unloading the substrate W from the stage 24.

As described above, the substrate processing apparatus 100 and the position detection method make it possible to accurately capture images of each fixed-side imaging target 17 and each rotation-side imaging target 25 using the imaging device 81 through the intermediate correction lens 85, and to detect the positions thereof. As a result, the substrate processing apparatus 100 and the position detection method make it possible to accurately position the stage 24.

The substrate processing apparatus 100 and the position detection method of the present disclosure are not limited to the above-described embodiment, and may take various modification examples. For example, the substrate processing apparatus 100 may not include the polarizing plate 86 in a case where strong reflected light is not generated on the rotary table 2 or the container body 12. In addition, the substrate processing apparatus 100 may omit the HDR processing or the like in a case where there is a small decrease in luminance of the imaging information.

In addition, for example, insofar as at least two rotation-side imaging targets 25 are provided for each stage 24, the substrate processing apparatus 100 may detect the position of the stage 24 based on the positional relationship with an appropriate configuration of the processing container 1 or the positional relationship in the imaging range. Therefore, the substrate processing apparatus 100 does not need to have the fixed-side imaging target 17. For example, in a case where the position of the rotation-side imaging target 25 is extracted using the position of each pixel of the imaging information, the substrate processing apparatus 100 may calculate the position of the rotation-side imaging target 25 regardless of the Hough transform.

Further, the substrate processing apparatus 100 may be configured to have the intermediate correction lens 85 below the transmission window 11w (inside the processing container 1). Alternatively, the substrate processing apparatus 100 may be configured with the intermediate correction lens 85 applied instead of the transmission window 11w.

Furthermore, although the rotary table 2 having a plurality of fixed concave stages 24 has been described in the embodiment, the substrate processing apparatus 100 may be configured to rotate (spin) each stage 24 separately from the rotation (revolution) of the rotary table 2. In the case of a configuration in which each stage 24 is rotated, at least two imaging targets (for example, recesses) are also formed in each stage 24, and the position of the stage 24 in the rotational direction is recognized by the imaging device 81, which makes it possible to position the stage 24.

The technical ideas and effects of the present disclosure described in the above embodiment will be described below.

According to a first aspect of the present disclosure, there is provided a substrate processing apparatus 100 including: a processing container 1; a rotary table 2 rotatably provided inside the processing container 1 and including a stage 24 on which a substrate W is placed; an imaging device 81 fixed to the processing container 1 and capable of capturing an image of a portion of the rotary table 2; and a control unit (an imaging control unit 81a or a control unit 90) that processes imaging information of the imaging device 81, in which the rotary table 2 includes at least two rotation-side imaging targets 25 spaced apart from each other at positions corresponding to the stage, the control unit 90 rotates the rotary table 2 such that, when an image of the rotary table 2 is captured, the imaging device 81 is located between the two rotation-side imaging targets 25 in a plan view of the imaging device 81 and the rotary table 2, and an intermediate correction lens 85 is provided between the imaging device 81 and the rotary table 2 in a side view of the imaging device 81 and the rotary table 2, to correct a viewing angle direction VD of the imaging device 81 in a direction orthogonal to a surface of the rotary table 2.

According to the above, the substrate processing apparatus 100 includes the intermediate correction lens 85, and thus it is possible to clearly capture at least two rotation-side imaging targets 25 when the imaging device 81 captured an image. The control unit (the imaging control unit 81a, the control unit 90) may accurately recognize the position of the stage 24 of the rotary table 2 by using this imaging information. This enables the substrate processing apparatus 100 to accurately position the stage 24 by rotating the rotary table 2, and to accurately place the substrate W on the stage 24.

In addition, the processing container 1 includes at least two fixed-side imaging targets 17 spaced apart from each other in an imaging range F captured by the imaging device 81, and the imaging device 81 captures images of the two rotation-side imaging targets 25 and the two fixed-side imaging targets 17 through the intermediate correction lens 85. This allows the substrate processing apparatus 100 to recognize the shift between the imaging targets by using information on the two rotation-side imaging targets 25 and the two fixed-side imaging targets 17.

In addition, the control unit (the imaging control unit 81a or the control unit 90) performs an image processing on the two rotation-side imaging targets 25 and the two fixed-side imaging targets 17 included in the imaging information to detect positions of the two rotation-side imaging targets 25 and positions of the two fixed-side imaging targets 17. This allows the substrate processing apparatus 100 to more accurately calculate the positional shift of the stage 24 based on the positions of the two rotation-side imaging targets 25 and the positions of the two fixed-side imaging targets 17.

In addition, the control unit (the imaging control unit 81a, the control unit 90) performs a high dynamic range (HDR) processing to improve luminance of the imaging information as the image processing. This allows the application of the intermediate correction lens 85 to improve the luminance of the imaging information even when there is a decrease in the luminance, and to increase the accuracy of identification of the two rotation-side imaging targets 25 and the two fixed-side imaging targets 17.

In addition, the control unit (the imaging control unit 81a or the control unit 90) performs Hough transform on the two rotation-side imaging targets 25 as the image processing, thereby detecting a predetermined shape. This allows the substrate processing apparatus 100 to more accurately calculate the positions of the two rotation-side imaging targets 25 based on the Hough transformed shapes.

In addition, a polarizing plate 86 is provided between the intermediate correction lens 85 and the rotary table 2 in a side view of the imaging device 81 and the rotary table 2. This allows the substrate processing apparatus 100 to remove reflected light from the processing container 1 and the rotary table 2 using the polarizing plate 86, and to stably execute the extraction of the two rotation-side imaging targets 25.

In addition, the imaging device 81 is provided outside the processing container 1, the processing container 1 has a transmission window 11w through which the imaging device 81 is capable of capturing an image of the rotary table 2, and the intermediate correction lens 85 is provided between the transmission window 11w and the imaging device 81. This allows the substrate processing apparatus 100 to suppress contamination of the intermediate correction lens 85 concomitant with substrate processing.

In addition, the two rotation-side imaging targets 25 are recesses 251 recessed from the surface of the rotary table 2 in the thickness direction. This allows the substrate processing apparatus 100 to reduce manufacturing costs, and allows the imaging device 81 and the intermediate correction lens 85 to capture straight images of the recesses 251 and properly detect the positions thereof.

In addition, according to a second aspect of the present disclosure, there is provided a method of detecting a position of a substrate processing apparatus 100, the apparatus including a processing container 1, a rotary table 2 rotatably provided inside the processing container 1, including a stage 24 on which a substrate W is placed, and having at least two rotation-side imaging targets 25 spaced apart from each other at positions corresponding to the stage 24, and an imaging device 81 fixed to the processing container 1 and capable of capturing an image of a portion of the rotary table 2, the method including: (A) rotating the rotary table 2 such that the imaging device 81 is located between the two rotation-side imaging targets 25 in a plan view of the imaging device 81 and the rotary table 2; (B) after (A), capturing images of the two rotation-side imaging targets 25 by correcting a viewing angle direction VD of the imaging device 81 in a direction orthogonal to a surface of the rotary table 2 through an intermediate correction lens 85 provided between the imaging device 81 and the rotary table 2 in a side view of the imaging device 81 and the rotary table 2; (C) performing an image processing on imaging information captured by the imaging device 81 in (B), thereby detecting positions of the two rotation-side imaging targets 25. Even in this case, the position detection method makes it possible to accurately recognize the position of the stage 24 of the rotary table 2.

According to an aspect, the position of the stage of the rotary table may be recognized with high accuracy.

From the foregoing content, it will be appreciated that various embodiments of the present disclosure have been described herein for purposes of illustration, and that various modifications can be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container;
a rotary table rotatably provided inside the processing container and including a stage on which a substrate is placed;
an imaging device fixed to the processing container and configured to capture an image of a portion of the rotary table; and
a controller configured to process imaging information of the imaging device,
wherein the rotary table includes at least two rotation-side imaging targets spaced apart from each other at positions corresponding to the stage,
the controller rotates the rotary table such that, when an image of the rotary table is captured, the imaging device is located between the two rotation-side imaging targets in a plan view of the imaging device and the rotary table, and
an intermediate correction lens is provided between the imaging device and the rotary table in a side view of the imaging device and the rotary table, to correct a viewing angle direction of the imaging device in a direction orthogonal to a surface of the rotary table.

2. The substrate processing apparatus according to claim 1, wherein the processing container includes at least two fixed-side imaging targets spaced apart from each other in an imaging range imaged by the imaging device, and
the imaging device captures images of the two rotation-side imaging targets and the two fixed-side imaging targets through the intermediate correction lens.

3. The substrate processing apparatus according to claim 2, wherein the controller performs an image processing on the two rotation-side imaging targets and the two fixed-side imaging targets included in the imaging information to detect positions of the two rotation-side imaging targets and positions of the two fixed-side imaging targets.

4. The substrate processing apparatus according to claim 3, wherein the controller performs a high dynamic range (HDR) processing to improve luminance of the imaging information as the image processing.

5. The substrate processing apparatus according to claim 3, wherein the controller performs a Hough transform on the two rotation-side imaging targets as the image processing, thereby detecting a predetermined shape.

6. The substrate processing apparatus according to claim 1, wherein a polarizing plate is provided between the intermediate correction lens and the rotary table in a side view of the imaging device and the rotary table.

7. The substrate processing apparatus according to claim 1, wherein the imaging device is provided outside the processing container,
the processing container has a transmission window through which the imaging device is capable of capturing an image of the rotary table, and
the intermediate correction lens is provided between the transmission window and the imaging device.

8. The substrate processing apparatus according to claim 1, wherein the two rotation-side imaging targets are recesses recessed from the surface of the rotary table in a thickness direction thereof.

9. A position detection method comprising:
providing a substrate processing apparatus including:
a processing container,
a rotary table rotatably provided inside the processing container, including a stage on which a substrate is placed, and having at least two rotation-side imaging targets spaced apart from each other at positions corresponding to the stage, and
an imaging device fixed to the processing container and configured to capture an image of a portion of the rotary table;
rotating the rotary table such that the imaging device is located between the two rotation-side imaging targets in a plan view of the imaging device and the rotary table;
after the rotating, capturing images of the two rotation-side imaging targets by correcting a viewing angle direction of the imaging device in a direction orthogonal to a surface of the rotary table through an intermediate correction lens provided between the imaging device and the rotary table in a side view of the imaging device and the rotary table; and
performing an image processing on imaging information captured by the imaging device in the capturing, thereby detecting positions of the two rotation-side imaging targets.
